(19) United States
(12) Patent Application Publication
(10) Pub. No.: US 2019/0362965 A1
(43) Pub. Date: Nov. 28, 2019

(54) METHODS OF PATTERNING A WAFER SUBSTRATE

(71) Applicant: Applied Materials, Inc., Santa Clara, CA (US)

(72) Inventors: Keith Tatseun WONG, Los Gatos, CA (US); HyoJin KIM, San Jose, CA (US); Srinivas D. NEMANI, Sunnyvale, CA (US); Seshadri RAMASWAMI, Saratoga, CA (US); Ellie Y. YIEH, San Jose, CA (US)

(21) Appl. No.: 16/396,173

(22) Filed: Apr. 26, 2019

Related U.S. Application Data
(60) Provisional application No. 62/676,116, filed on May 24, 2018.

(51) Int. Cl. H01L 21/02; H01L 23/29; H01L 21/027; H01L 21/311

(52) U.S. Cl. CPC H01L 21/02126; H01L 23/29; H01L 21/0234; H01L 21/31144; H01L 21/0271

(57) ABSTRACT

Embodiments of the present disclosure provide for patterned substrates and methods of forming a patterned substrate, particularly a self-assembly pattern on a surface of a substrate, such as a host substrate, subsequently used in a chip to wafer (C2W) direct bonding process. In one embodiment, a method of patterning a substrate includes depositing a first material layer on a surface of a substrate, depositing a resist layer on the first material layer, patterning the resist layer to form a plurality of openings therethrough, transferring the pattern in the resist layer to the first material layer to form a plurality of self-assembly regions each comprising a hydrophilic assembly surface, and removing the resist layer to expose one or more hydrophobic bounding surfaces. Herein, the first material layer comprises a hydrophobic material.

### CROSS-REFERENCE TO RELATED APPLICATIONS

This application claims priority to U.S. Provisional Application Ser. No. 62/676,116, filed on May 24, 2018, which is herein incorporated by reference in its entirety.

### BACKGROUND

### Field

Embodiments described herein generally relate to the field of electronic device manufacturing, and more particularly, to methods of forming patterns of hydrophilic and hydrophobic regions on a host substrate surface used in chip to wafer (C2W) direct bonding electronic device manufacturing or electronic device packaging schemes.

### Description of the Related Art

Chip to wafer (C2W) direct bonding has a wide range of applications in semiconductor device manufacturing and electronic device packaging schemes. C2W describes an assembly method of positioning one or more singulated known-good-dies (KGDs), herein singulated devices, on a host substrate. Direct bonding describes methods of joining two substrate surfaces at an atomic level, i.e., through chemical bonds between the substrates, without the use of intermediate layers, such as conductive adhesive layers, solders, etc., interposed therebetween. Direct bonding methods used in C2W assembly processes include low temperature direct bonding methods, e.g., less than 450° C., such as a thermal compression bonding method where a load is applied to a plurality of KGDs (singulated devices) positioned on a host substrate and one or both of the plurality of singulated devices and host substrate are heated under vacuum to facilitate the formation of atomic bonds between the surfaces, typically metal surfaces, such as metal contact pads, thereof.

In one example, C2W direct bonding is used to form the first layer, i.e., a plurality of singulated devices disposed on a host substrate, in a 3D-IC integration scheme. Typically, in a 3D-IC integration scheme a plurality of devices are vertically stacked and interconnected using through silicon vias (TSV's) or daisy chained metal-to-metal connections. C2W direct bonding in a 3D-IC integration scheme, as opposed to wafer to wafer (W2W) bonding desirably allows for integration of devices of difference sizes which enables increased manufacturing flexibility and 3D-IC system customization.

In another example, C2W direct bonding is used to bond a plurality of singulated devices to a host substrate having I/O terminal redistribution layers (RDLs) formed therein. RDLs are used to redistribute I/O terminals on the surfaces of the singulated devices to areas external thereto in fan out wafer level packaging (FOWLP) schemes. In some C2W assembly schemes, each of a plurality of singulated devices are positioned face down (active surface down) on a respective assembly region on the host substrate and electrical contacts or via interconnects on the surfaces of the singulated devices are aligned with via interconnects disposed in the surface of the host substrate.

Often, each of the plurality of singulated devices are positioned on the surface of the host substrate using a pick and place process and are then finely aligned with a respective assembly region on the host substrate using a capillary self-assembly method. Capillary self-assembly, also known as surface tension-driven self-alignment, describes an assembly method where hydrophilic surfaces of a singulated device self-align with hydrophilic surfaces of a host substrate using capillary forces from an assembly fluid, such as water, disposed therebetween. The assembly fluid is then vaporized from the interfaces between the self-assembled devices and the host substrate before direct bonding thereof. Often, the alignment accuracy of capillary self-assembly is determined, at least in part, by a difference between the hydrophilicity of hydrophilic surfaces in an assembly region of a host substrate compared to the hydrophobicity of surfaces bounding the hydrophilic surfaces and adjacent thereto, herein hydrophobic bounding surfaces. Typically, increased differences in the hydrophobicity of the respective hydrophilic surfaces and adjacent hydrophobic at bounding surfaces therebetween desirably results in increased lateral alignment accuracy of the singulated device on the host substrate.

Conventionally, C2W capillary self-assembly schemes rely on the respective inherent hydrophilicity and hydrophobicity of interconnect features previously formed in a surface of the host substrate and dielectric surfaces disposed thereabout. However, the inherent hydrophilicity and hydrophobicity of interconnect features on the surfaces of the host substrate and the dielectric surfaces disposed thereabout are insufficient to provide the required alignment accuracies needed as interconnect feature pattern densities increase and dimensions of interconnect features continue to shrink.

Accordingly, there is a need in the art for improved self-assembly patterned substrates, and methods of forming self-assembly patterned substrates, such as host substrates used in C2W direct bonding electronic device manufacturing or electronic device packaging schemes.

### SUMMARY

Embodiments of the present disclosure provide for patterned substrates and methods of forming a patterned substrate, particularly a self-assembly pattern on a surface of a substrate, such as a host substrate subsequently used in a chip to wafer (C2W) direct bonding process.

In one embodiment, a method of patterning a substrate includes depositing a first material layer on the substrate, depositing a resist layer on the first material layer, and patterning the resist layer to form a plurality of openings therein. The method further includes transferring the pattern in the resist layer to the first material layer to form a plurality of self-assembly regions and removing the resist layer to expose one or more hydrophobic surfaces bounding the plurality of self-assembly regions. Here, the first material layer features a hydrophobic surface and each of the self-assembly regions comprises a hydrophilic assembly surface.

In another embodiment, a method of patterning a substrate includes depositing a first material layer on a surface of a substrate, wherein the first material layer comprises a hydrophobic material, and exposing portions of the first material layer to laser radiation to form a plurality of self-assembly regions.

In another embodiment, a patterned substrate includes a hydrophobic material layer comprising a silicon based dielectric material, the hydrophobic material layer having a plurality of self-assembly regions disposed therein, where each of the plurality of self-assembly regions comprises a hydrophilic surface.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a flow diagram setting forth a method of patterning a substrate, according to one embodiment.

FIGS. 2A-2F schematically illustrate aspects of the intermediate and final results of the method set forth in FIG. 1, according to one embodiment.

FIGS. 3A-3B schematically illustrate aspects of capillary self-assembly of a singulated device on a patterned substrate formed according to a method set forth herein, according to one embodiment.

FIG. 4 is a flow diagram setting forth a method of patterning a substrate, according to another embodiment.

FIG. 5A-5D schematically illustrate aspects of the intermediate and final results of the method set forth in FIG. 4, according to one embodiment.

FIG. 6 is a schematic plan view of a patterned substrate formed using the methods described herein, according to another embodiment.

### DETAILED DESCRIPTION

Embodiments of the present disclosure provide for patterned substrates and methods of patterning a substrate, particularly a self-assembly pattern on a surface of a substrate, such as a host substrate subsequently used in a chip to wafer (C2W) direct bonding process. The self-assembly patterns formed herein typically include a plurality of assembly regions comprising hydrophilic surfaces bounded by one or more hydrophobic surfaces, herein “bounding surfaces”, which beneficially enable highly accurate self-assembly, i.e., self-alignment, of singulated devices on a host substrate and facilitate direct bonding therebetween. Hydrophilic herein describes surfaces where a water droplet disposed thereon forms a contact angle of no more than 30°. Hydrophobic herein describes surfaces where a water droplet disposed thereon forms a contact angle of no less than 70°.

In some direct bonding processes, it is desirable to pre-treat one or both surfaces of the device and the host substrate to promote direct bonding therebetween, such as direct bonding of dielectric surfaces of device and host substrate. Unfortunately, the pre-treatment methods, e.g., plasma treatment, used to activate the assembly surfaces of the host substrate may also undesirably reduce the hydrophobicity of bounding surfaces adjacent thereto. Reduced hydrophobicity of bounding surfaces adjacent to the hydrophilic assembly surfaces on the host substrate undesirably results in decreased lateral alignment accuracy during a subsequent self-assembly process. Therefore, some embodiments described herein provide for the formation of plasma activated hydrophilic assembly surfaces on the host substrate without reducing the hydrophobicity of bounding surfaces adjacent thereto.

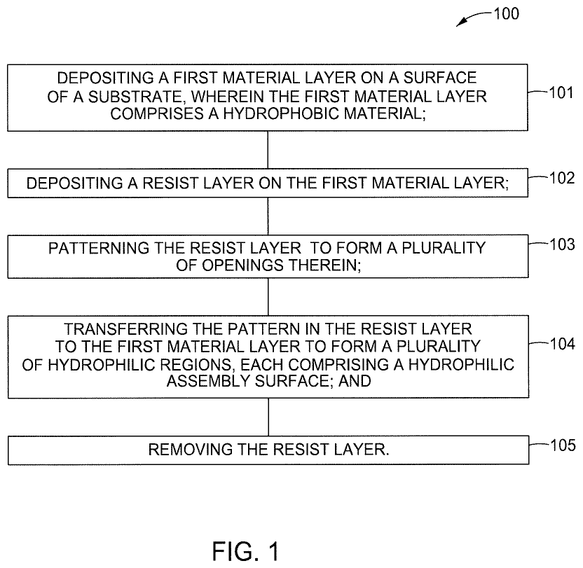

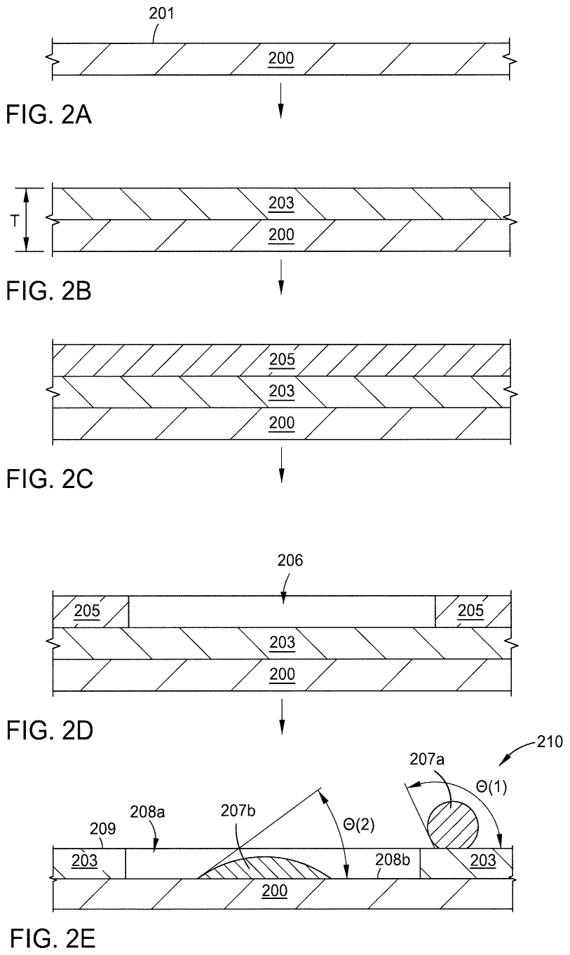

FIG. 1 is a flow diagram of a method of patterning a substrate, according to one embodiment. FIGS. 2A-2F illustrate intermediate and final results of the method set forth in FIG. 1. At activity 101 the method 100 includes depositing a first material layer 203 on the surface 201 of a host substrate, such as the substrate 200. Herein, the first material layer 203 comprises a material having a hydrophobic surface. In some embodiments, the first material layer 203 is a silicon-based dielectric material, such as SiO₂, SiN, SiOₓC_{y}, or SiOₓN_{y} deposited using a chemical vapor deposition (CVD) process or a plasma enhanced CVD (PECVD) process in a CVD or PECVD processing chamber. Exemplary processing chambers suitable for depositing the first material layer 203 include substrate processing chambers available in Centura®, Endura®, and Producer® processing systems from Applied Materials, Inc., of Santa Clara, Calif. or other suitable CVD and PECVD processing chambers available from other manufacturers. In some embodiments, the first material layer 203 further comprises one of fluorine (F), carbon (C), hydrogen (H), or a combination thereof.

In one embodiment, the first material layer 203 comprises SiCOH deposited using a PECVD process which includes flowing one or more precursors comprising one or more organosilanes and one or more oxidizing gases into the processing volume of a processing chamber, forming a plasma of the one or more precursor gases, exposing the substrate 200 to the plasma, and depositing the first material layer 203 on the substrate 200. In some embodiments, the first material layer 203 comprises a low K carbon-containing silicon oxide dielectric material known as BLACK DIAMOND® I, BLACK DIAMOND® II, or BLACK DIAMOND® III, available from Applied Materials, Inc. Typically, the first material layer 203 is deposited to a thickness T of between about 100 Å and about 10 kÅ, such as between about 100 Å and about 5000 Å, for example between about 500 Å and about 5000 Å.

In some embodiments, the surface 201 of the substrate 200 is hydrophilic. In some embodiments, the surface 201 comprises one of silicon or a silicon based dielectric material, such as SiO₂, SiN, or SiOₓN_{y}. In some embodiments, the surface 201 further comprises a plurality of conductive features, such as metal lines, vias, or contact pads formed of metal, e.g., copper. In some embodiments, the surface 201 has been treated to increase the hydrophilicity thereof. Examples of treatment methods to increase the hydrophilicity of the surface 201 include exposure to O₃, UV-O₃, O₂-plasma, H₂O plasma, N₂ plasma, SC1 solution (mixture of NH₃, H₂O₂, and H₂O), or combinations thereof. In some embodiments, the method 100 includes depositing a second material layer (not shown) having a hydrophilic surface, i.e., a hydrophilic material layer, on the substrate 200 before depositing the first material layer 203. Typically, the second material layer comprises a silicon based dielectric material, such as SiO₂, SiN, or SiOₓN_{y}. In some embodiments, the surface 201 or a second material layer disposed thereon is substantially free of one or both of carbon and fluoride. Herein, substantially free of carbon or fluoride means that the surface 201 does not have a respective moiety thereof. In some embodiments, the substrate 200 further includes a plurality of features formed therein (not shown), for example a plurality of conductive features, such as metal interconnect features, forming an I/O terminal redistribution layer (RDL) or a plurality of through vias, such as through vias used in a through integrated fan out via (TIV) packaging scheme. In some embodiments, the substrate 200 comprises a plurality of electronic devices.

At activities 102 and 103 the method 100 respectively includes depositing a resist layer 205 (shown in FIG. 2C) on the first material layer 203 and forming a pattern therein (shown in FIG. 2D) using a lithography process, such as a photolithography, imprint lithography, or a digital lithography process followed by developing the resist layer 205 and removing a portion thereof in a solvent to form the openings 206 of FIG. 2D. Herein, the pattern comprises a plurality of openings 206 formed through the resist layer 205. Typically, the resist layer 205 comprises a resin material which is curable using electromagnetic radiation, such as ultra-violet (UV) radiation, or is thermally cured, for example during a thermal imprint lithography process. The resist layer 205 herein is deposited or dispensed on the first material layer 203 using a suitable method, for example slot die coating, inkjet printing, gravure printing, spin-on coating, or a combination thereof.

At activity 104 the method 100 includes transferring the pattern, i.e., the plurality of openings 206, formed in the resist layer 205 to the first material layer 203. In some embodiments, transferring the pattern formed in the resist layer 205 to the first material layer 203 includes extending the plurality of openings 206 through the first material layer 203 to expose the surface 201 of the substrate 200 therebeneath. Herein, transferring the pattern form in the resist layer 205 to the first material layer 203 forms a plurality of self-assembly regions 208a, where each of the self-assembly regions 208a comprises a hydrophilic assembly surface 208b. Typically, a dry etching process, such as a reactive ion etch (RIE) process, is used to extend the plurality of openings 206 through the first material layer 203 by removing the portion of first material layer 203 exposed in the openings 206 in the resist layer 205. Exemplary processing chambers suitable for extending the plurality of openings 206 through or into the first material layer 203 include processing chambers available on Centris®, Centrura®, and Producer® substrate processing systems from Applied Materials, Inc., of Santa Clara, Calif. or other suitable plasma enhanced etch processing chambers available from other manufacturers.

In some embodiments, extending the plurality of openings 206 through the first material layer 203 includes exposing the substrate 200, having the first material layer 203 and patterned resist layer 205 disposed thereon, to a plasma formed from a processing gas comprising one or more reactive gases, such as one or more fluorocarbons. In some embodiments, the processing gas further comprises one or a combination of O₂ and an inert gas, such as He, Ne, Ar, Kr, Xe, or combinations thereof.

Typically, exposing the first material layer 203 to the processing plasma to extend the plurality of openings 206 therethrough or thereinto also reduces the hydrophobicity of the first material layer 203 at surfaces thereof. For example, in embodiments where first material layer 203 comprises carbon-hydrogen groups, such as CH₃ groups, exposing the first material layer 203 to the processing plasma strips the hydrophobic carbon-hydrogen groups from the first material layer 203 to change the surfaces thereof from hydrophobic to hydrophilic. Therefore, in some embodiments, the plurality of openings 206 are only partially extended into (and not through) the first material layer 203 so that the substrate 200 and the surface 201 thereof are not exposed and a hydrophilic recess having an area of the opening is formed in first material layer 203.

In some embodiments, transferring the pattern formed in the resist layer 205 includes forming the plurality of self-assembly regions 208a each having a hydrophilic assembly surface 208b on the surface of the first material layer 203 by exposing surfaces of the first material layer 203 thereof to a plasma, such as an argon or nitrogen plasma, through the plurality of openings 206.

At activity 105 the method 100 includes removing the resist layer 205 using a solvent based resist stripping process to expose one or more hydrophobic bounding surfaces 209 disposed therebeneath. Using a solvent base resist stripping process beneficially enables removing the resist layer 205 without undesirably decreasing the hydrophobicity of the bounding surfaces 209. Examples of suitable solvents include alkanes, aromatics, ketones, such as acetone, ethers, esters, alcohols, carboxylic acids, and combinations thereof.

FIG. 2E illustrates a portion of a patterned substrate 210 formed according to the method 100. Herein, a contact angle θ(1) of a water droplet 207a disposed on the hydrophobic bounding surface 209 is more than about 70°, such as more than 80°, more than about 85°, or between about 80° and about 110°, for example between about 80° and about 100°, such as about 90°. A contact angle θ(2) of a water droplet 207b disposed on a hydrophilic assembly surface 208b is less than about 30°, such as less than about 20°, less than about 10°, or for example less than about 5°. Typically, larger differences between the respective contact angles of water droplets dispose on the hydrophilic assembly surfaces 208b and the hydrophobic bounding surfaces 209 adjacent thereto desirably results in increased lateral alignment accuracy of a singulated device during a subsequent C2W self-assembly process. In some embodiments, a difference between the contact angle θ(2) of a water droplet 207a disposed on the one or more hydrophobic bounding surfaces 209 and a contact angle θ(1) of a water droplet 207b disposed on the hydrophilic assembly surface 208b is more than about 50°, such as more than about 60°, for example more than about 70°.

FIG. 2F is a schematic plan view of the patterned substrate 210 formed according the method 100, according to one embodiment. Herein, the patterned substrate 210 comprises a plurality of self-assembly regions 208a where each of the self-assembly regions 208a comprises a hydrophilic assembly surface 208b bounded by a hydrophobic bounding surface 209. As shown in FIG. 2F the shape and dimensions of each of the self-assembly regions 208a corresponds to the shape and dimensions of an active surface to be assembled singulated device (not shown). However, it is contemplated that more complicated shapes and patterns may be formed using the methods set forth herein, including self-assembly regions 208a having one or more hydrophobic surfaces disposed therein or extending thereinto, where the more complicated shapes and patterns comprise hydrophilic and hydrophobic surfaces corresponding to hydrophilic and hydrophobic surfaces on the active surface a to be assembled singulated device.

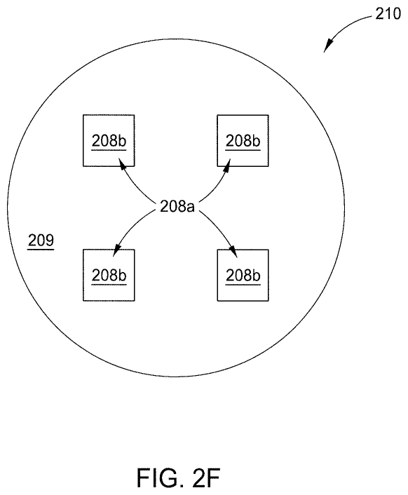

In some embodiments, the method 100 further includes positioning a plurality of singulated devices 300 on the patterned host substrate 210 using a capillary self-assembly method as illustrated in FIGS. 3A-3B. Typically, each of the plurality of singulated devices 300 comprises a hydrophilic surface, herein the active surface 301, formed of a dielectric material, such as an oxide or nitride material, having a plurality of metal features (not shown) formed therein. Herein, the plurality of singulated devices 300 are positioned face down (active surface 301 down) roughly proximate to a corresponding hydrophilic assembly surface 208b on the patterned host substrate 210, having an assembly fluid 302, such as water, disposed thereon. Herein, roughly proximate to, or roughly positioned on, means that the active surface 301 is at least in contact with the assembly fluid 302. Once roughly positioned, a singulated device 300 will spontaneously self-align with the hydrophilic assembly surface 208b to minimize the surface energy of the assembly fluid 302 at interfacial surfaces between the singulated device 300 and the patterned host substrate 210. Typically, the assembly fluid 302 is then vaporized from between the singulated device 300 and the assembly surface 208b to form the self-assembled C2W substrate 310 shown in FIG. 3B. In some embodiments, the method further includes directly bonding the hydrophilic assembly surface 208 and the hydrophilic active surface 301 using a low temperature, e.g., <450 ° C., direct bonding method, such as a thermal compression bonding method.

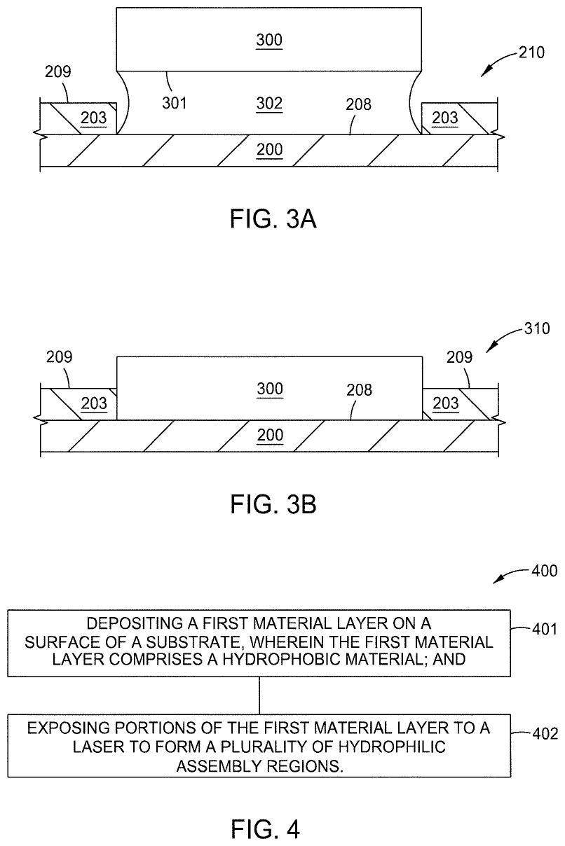

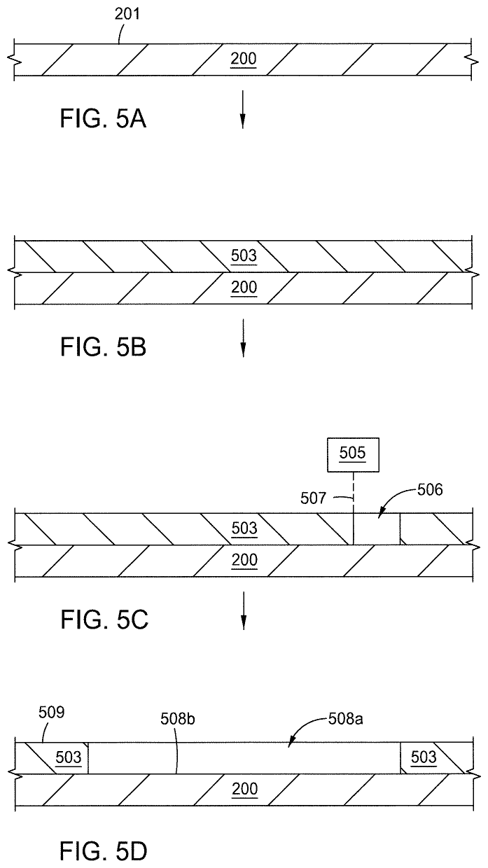

FIG. 4 is a flow diagram of a method of forming a patterned surface on a substrate, according to another embodiment. FIGS. 5A-5D illustrate intermediate and final results of the method set forth in FIG. 4. At activity 401 the method 400 includes depositing a first material layer 503 on a host substrate, such as the substrate 200 featuring a hydrophilic material surface 201 described above in FIGS. 2A-2E. In some embodiments, the method 400 further includes treating the hydrophilic material surface 201 to increase the hydrophilicity thereof. Examples of suitable methods of treating the hydrophilic material surface 201 are described in reference to the method 100 set forth in FIG. 1. In some embodiments, the method 400 further includes depositing a second material layer (not shown) having a hydrophilic surface, i.e., a hydrophilic material layer, on the substrate 200 before depositing the first material layer 503. Examples of suitable second material layers are described in reference to the method 100 set forth in FIG. 1.

Herein, the first material layer 503 comprises a hydrophobic material which is removable from the substrate 200 by a laser irradiation method. In some embodiments, the first material layer 503 comprises a self-assembled monolayer. In some embodiments the self-assembled monolayer comprises a hydrophobic alkyl tail (saturated hydrocarbon chain with 6-18 carbons) with a head group chosen to interact with the underlying surface. Examples of head groups include thiols, carboxylic acids, chlorosilanes, aminosilanes, phosphonic acids, alkenes, and alkynes.

At activity 402 the method 400 includes exposing, in a desired pattern, the first material layer 503 to laser radiation 507 from a laser radiation source 505 to form a plurality of openings 506 therethrough. Forming the plurality of openings 506 through the first material layer 503 desirably exposes the hydrophilic material surface 501 of the substrate 200 therebeneath to form a pattern comprising a plurality of self-assembly regions 508 surrounded by one or more hydrophobic bounding surfaces 509. Herein, a contact angle of a water droplet (not shown) disposed on the hydrophobic bounding surface 509 is more than about 70°, such as more than 80°, more than about 85°, or between about 80° and about 110°, for example between about 80° and about 100°, such as about 90°. A contact angle of a droplet of water (not shown) disposed on the hydrophilic surface 501 in the hydrophilic assembly region 508 is less than about 30°, such as less than about 20°, less than about 10°, or for example less than about 5°. Typically, larger differences between the hydrophilicity of surfaces in the assembly regions and the bounding surfaces adjacent thereto desirably results in increased lateral alignment accuracy of a singulated device during a subsequent C2W self-assembly process. In some embodiments, a difference between the contact angle of a water droplet disposed on the hydrophobic bounding surfaces 209 and a contact angle θ(1) of a water droplet disposed on the hydrophilic assembly surface 208b is more than about 50°, such as more than about 60°, for example more than about 70°.

In some embodiments, the method 400 further includes positioning a plurality of singulated devices 300 on the patterned host substrate 510 using a capillary self-assembly method as illustrated in FIGS. 3A-3B and described above in reference to the method 100.

Embodiments provided herein enable highly accurate self-alignment of singulated devices on a host substrate used in C2W assembly schemes and further facilitate direct bonding of dielectric surfaces thereof. In some embodiments, the methods described herein allow for activation, such as plasma activation, of dielectric surfaces of the host substrate without reducing the hydrophobicity of bounding surfaces adjacent thereto. Activation of the dielectric assembly surfaces on the host substrate desirably increases the bond strength between the dielectric surfaces of the host substrate and dielectric surfaces of the singulated devices subsequently directly bonded thereto. Further, the methods and patterned substrates described herein may be used in other applications where it is desirable to form a pattern of hydrophilic surfaces bounded by hydrophobic surfaces. For example, the methods and patterned substrates herein may be used to form fluid channels in the surface of a substrate for use in microfluidic applications.

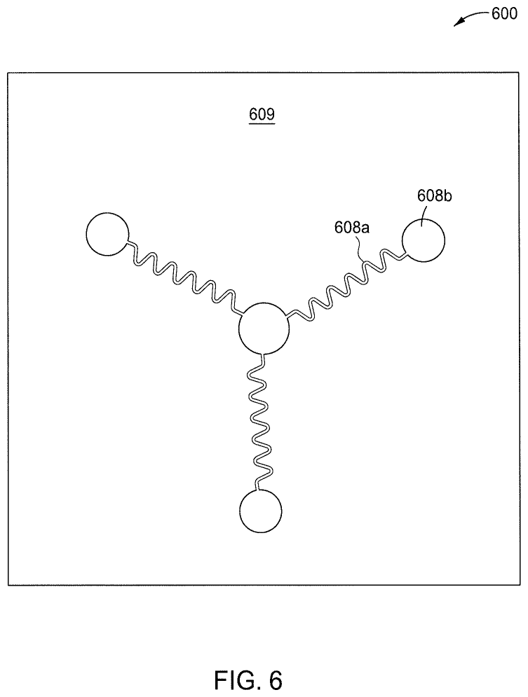

FIG. 6 is a schematic plan view of a patterned substrate formed using one or a combination of the methods described herein, according to one embodiment. Herein, the patterned substrate 600 includes one or more fluid channels 606 each comprising a hydrophilic surface 601 surrounded by and adjacent on or more hydrophobic bounding surfaces 609. Typically, the one or more fluid channels 606 are further defined by a surface of a layer (not shown), such as a laminated layer (not shown) or a second patterned substrate (not shown), disposed on the surface of the patterned substrate 600 and bonded thereto. In some embodiments, a second patterned substrate is aligned with the first patterned substrate using the methods described herein. In some embodiments, the second patterned substrate is directly bonded to the first patterned substrate.

While the foregoing is directed to embodiments of the present disclosure, other and further embodiments of the disclosure may be devised without departing from the basic scope thereof, and the scope thereof is determined by the claims that follow.

1. A method of patterning a substrate, comprising:
depositing a first material layer on a substrate, wherein the first material layer comprises a hydrophobic surface;
depositing a resist layer on the first material layer;
patterning the resist layer to form a plurality of openings therein;
transferring the pattern in the resist layer to the first material layer to form a plurality of self-assembly regions each comprising a hydrophilic assembly surface; and
removing the resist layer to expose one or more hydrophobic surfaces bounding individual ones of the plurality of self-assembly regions.

2. The method of claim 1, further comprising depositing a second material layer on the substrate before depositing the first material layer.

3. The method of claim 1, wherein transferring the pattern in the resist layer to the first material layer comprises only partially extending the plurality of openings formed through the resist layer into the first material layer to form the plurality of self-assembly regions.

4. The method of claim 1, wherein the resist layer is removed using a solvent comprising an alkane, an aromatic, a ketone, an ether, an ester, an alcohol, a carboxylic acid, or a combinations thereof.

5. The method of claim 1, wherein the first material layer comprises a silicon based dielectric material.

6. The method of claim 5, wherein the first material layer further comprises fluorine, carbon, hydrogen, or a combination thereof.

7. The method of claim 6, wherein the first material layer comprises SiCOH.

8. The method of claim 1, wherein a surface of the substrate comprises silicon or a silicon based dielectric material.

9. The method of claim 8, wherein the surface of the substrate is hydrophilic.

10. The method of claim 9, wherein transferring the pattern formed in the resist layer to the first material layer comprises forming a plurality of openings through the first material layer to form the plurality of self-assembly regions.

11. The method of claim 8, further comprising treating the surface of the substrate to increase the hydrophilicity thereof before depositing the first material layer.

12. The method of claim 1, wherein transferring the pattern in the resist layer comprises plasma treating a surface of the first material layer through the plurality of openings to form the plurality of self-assembly regions.

13. The method of claim 12, wherein a plasma used to treat the surface of the first material layer is formed of an inert gas, N₂, or a combination thereof.

14. The method of claim 1, wherein a contact angle of a first water droplet disposed on the hydrophilic assembly surfaces is less than about 30°.

15. The method of claim 14, wherein a contact angle of a second water droplet disposed on the hydrophobic bounding surface is more than about 70°.

16. The method of claim 15, wherein the difference between the contact angle of the first water droplet and the contact angle of the second water droplet is more than about 50°.

17. A method of forming a patterned substrate, comprising:
depositing a first material layer on a surface of a substrate, wherein the first material layer comprises a hydrophobic material; and
exposing portions of the first material layer to a laser to form a plurality of self-assembly regions.

18. A patterned substrate, comprising:
a hydrophobic material layer comprising a silicon based dielectric material, the hydrophobic material layer having a plurality of openings formed therein; and
a plurality of self-assembly regions respectively defined by the plurality of openings, wherein each of the plurality of self-assembly regions comprises a hydrophilic assembly surface.

19. The patterned substrate of claim 18, wherein the silicon based dielectric material further comprises fluorine, carbon, hydrogen, or a combination thereof and wherein the hydrophilic assembly surface comprises a silicon or silicon based dielectric material.

20. The patterned substrate of claim 19, wherein
a contact angle of a first water droplet disposed on the hydrophilic assembly surfaces is less than about 30°,
a contact angle of a second water droplet disposed on the hydrophobic bounding surface is more than about 70°, and
the difference between the contact angle of the first water droplet and the contact angle of the second water droplet is more than about 50°.
